(19) United States
(12) Patent Application Publication
(10) Pub. No.: US 2024/0145553 A1
(43) Pub. Date: May 2, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Makoto KOSHIMIZU, Tokyo (JP); Yasutaka NAKASHIBA, Tokyo (JP); Tohru KAWAI, Tokyo (JP)

(21) Appl. No.: 18/051,935

(22) Filed: Nov. 2, 2022

(51) Int. Cl. H01L 29/40; H01L 29/66; H01L 29/78

(52) U.S. Cl. CPC H01L 29/402; H01L 29/401; H01L 29/66681; H01L 29/7816

(57) ABSTRACT

LDMOS having an n-type source region and a drain region formed on an upper surface of a semiconductor substrate, a gate electrode formed on the semiconductor substrate via a gate dielectric film, and a field plate electrode formed on the semiconductor substrate between the gate electrode and the drain region via a dielectric film having a larger film thickness than the gate dielectric film, is formed. Here, the field plate electrode has a larger work function than an n-type semiconductor region formed in the semiconductor substrate directly below the field plate electrode.

### BACKGROUND

The present invention relates to a semiconductor device and method of manufacturing the same, and can be suitably used, for example, in a semiconductor device including a field effect transistor including a dielectric film thicker than a gate dielectric film and a field plate electrode on the dielectric film on a substrate between a gate electrode and a drain region.

### THE BACKGROUND OF THE INVENTION

As one of MOSFET (Metal-Oxide-Semiconductor Field Effect Transistor), LDMOSFET (Laterally Diffused MOSFET, hereinafter simply referred to as “LDMOS”) is known. In LDMOS, an STI (Shallow Trench Isolation) may be provided under the gate electrode in order to relax an electric field between the gate electrode and the substrate.

There are disclosed techniques listed below.
[Non-Patent Document 1] K. Takahashi et al., “Hot-carrier induced off-state leakage current increase of LDMOS and approach to overcome the phenomenon,” 2018 IEEE 30th International Symposium on Power Semiconductor Devices and ICs (ISPSD), 2018, pp. 303-306

When a high electric field is applied between a source and a drain in LDMOS, hot carriers may be injected into STI to cause degradation. That is, a circuit malfunction, an increase in power consumption, and a degradation in product life may occur. As a countermeasure against such issues, it is conceivable to extend a length of STI. As described in Non-Patent Document 1, it is conceivable that a silicon oxide film thicker than the gate dielectric film is provided on a flat substrate without forming a STI, and a field plate electrode to which a gate potential is supplied is formed on the silicon oxide film.

### SUMMARY

However, in the above countermeasure, there is a problem that an interference of the potential at the interface between the silicon configuring substrate and the silicon oxide film is large, and the impact ionization rate is still large.

Other objects and novel features will become apparent from the description of this specification and the accompanying drawings.

The typical ones of the embodiments disclosed in the present application will be briefly described as follows.

In one embodiment, a semiconductor device includes an n-type source region and an n-type drain region formed in an upper surface of a semiconductor substrate, a gate electrode formed on the semiconductor substrate via a gate dielectric film, and a field plate electrode formed on the semiconductor substrate between the gate electrode and the drain region via a dielectric film having a larger thickness than the gate dielectric film. The field plate electrode has a larger work function than an n-type semiconductor region formed in the semiconductor substrate directly below the field plate electrode.

In one embodiment, a method of manufacturing a semiconductor device includes a step of forming an n-type source region, a p-type semiconductor region, an n-type semiconductor region, an n-type drain region, and a gate electrode located directly above the p-type semiconductor region via a gate dielectric film, which are arranged in an upper surface of a semiconductor substrate; a step of forming a laminated film formed of a first dielectric film having a larger film thickness than the gate dielectric film and a field plate electrode on the first dielectric film so as to continuously cover the upper surface of the semiconductor substrate between the gate electrode and the drain region and a side surface of the gate electrode; and a step of forming a sidewall spacer covering a side surface of the laminated film on the drain region side and exposing an upper surface of the drain region. Here, the field plate electrode has a work function that is greater than the work function of the n-type semiconductor region formed in the semiconductor substrate directly below the field plate electrode.

In another embodiment, A method of manufacturing a semiconductor device includes a step of forming an n-type source region, a p-type semiconductor region, an n-type semiconductor region, an n-type drain region, and a gate electrode located directly above the p-type semiconductor region via a gate dielectric film, which are arranged in an upper surface of a semiconductor substrate; a step of forming an interlayer dielectric film on the semiconductor substrate; and a step of forming a trench in an upper surface of the interlayer dielectric film between the gate electrode and the drain region and forming a field plate electrode in the trench. Here, a distance between a bottom surface of the trench and the upper surface of the semiconductor substrate is larger than the gate dielectric film, and the field plate electrode has a larger work function than the n-type semiconductor region formed in the semiconductor substrate directly below the field plate electrode.

### BRIEF DESCRIPTION OF THE DRAWINGS

FIG. 1 is a cross-sectional view showing a semiconductor device according to a first embodiment.

FIG. 2 is a planar layout showing the semiconductor device according to the first embodiment.

FIG. 3 is a cross-sectional view in A-A line of FIG. 2.

FIG. 4 is a diagram showing a potential in the semiconductor device according to the first embodiment.

FIG. 5 is a band diagram showing the modulation of the potential near the n-type field plate electrode.

FIG. 6 is a band diagram showing the modulation of the potential near the p-type field plate electrode.

FIG. 7 is a cross-sectional view and a graph showing the potential in the semiconductor device according to the first embodiment.

FIG. 8 is a cross-sectional view showing a manufacturing process of the semiconductor device according to the first embodiment.

FIG. 9 is a cross-sectional view showing a manufacturing process subsequent to FIG. 8.

FIG. 10 is a cross-sectional view showing a manufacturing process subsequent to FIG. 9.

FIG. 11 is a cross-sectional view showing a manufacturing process subsequent to FIG. 10.

FIG. 12 is a cross-sectional view showing a manufacturing process subsequent to FIG. 11.

FIG. 13 is a cross-sectional view showing a manufacturing process subsequent to FIG. 12.

FIG. 14 is a cross-sectional view showing a manufacturing process subsequent to FIG. 13.

FIG. 15 is a cross-sectional view showing a semiconductor device according to a second embodiment.

FIG. 16 is a cross-sectional view showing a manufacturing process of the semiconductor device according to the second embodiment.

FIG. 17 is a cross-sectional view showing a manufacturing process subsequent to FIG. 16.

FIG. 18 is a cross-sectional view showing a manufacturing process subsequent to FIG. 17.

FIG. 19 is a cross-sectional view showing a manufacturing process subsequent to FIG. 18.

FIG. 20 is a cross-sectional view showing a manufacturing process subsequent to FIG. 19.

FIG. 21 is a cross-sectional view showing a manufacturing process subsequent to FIG. 20.

FIG. 22 is a cross-sectional view showing a semiconductor device according to a third embodiment.

FIG. 23 is a cross-sectional view showing a manufacturing process of the semiconductor device according to the third embodiment.

FIG. 24 is a cross-sectional view showing a manufacturing process subsequent to FIG. 23.

FIG. 25 is a cross-sectional view showing a manufacturing process subsequent to FIG. 24.

FIG. 26 is a cross-sectional view showing a manufacturing process subsequent to FIG. 25.

FIG. 27 is a cross-sectional view showing a semiconductor device according to a fourth embodiment.

FIG. 28 is a cross-sectional view showing a manufacturing process of the semiconductor device according to the fourth embodiment.

FIG. 29 is a cross-sectional view showing a manufacturing process subsequent to FIG. 28.

FIG. 30 is a cross-sectional view showing a manufacturing process subsequent to FIG. 29.

FIG. 31 is a cross-sectional view showing a manufacturing process subsequent to FIG. 30.

FIG. 32 is a cross-sectional view showing a manufacturing process subsequent to FIG. 31.

FIG. 33 is a cross-sectional view showing a semiconductor device according to a first comparative example.

FIG. 34 is a cross-sectional view showing a semiconductor device according to a second comparative example.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In addition, in the following embodiments, the number of elements or the like (including the number, the number, the amount, the range, and the like) is not limited to the mentioned number, except the case where it is specified in particular or the case where it is obviously limited to a specific number in principle, and may be equal to or more than the mentioned number or may be equal to or less than the mentioned number.

Furthermore, in the following embodiments, the constituent elements (including element steps and the like) are not necessarily essential except for the case in which they are specifically specified, the case in which they are considered to be obviously essential in principle, and the like. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

### Room for Improvement

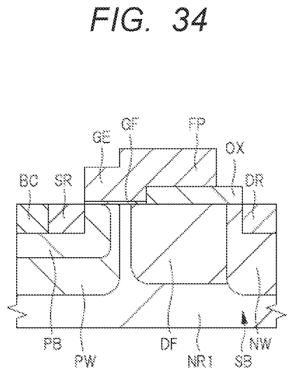

Details of room for improvement will be described below with reference to FIG. 33 and FIG. 34.

FIG. 33 shows a cross section of a semiconductor device including an n-channel type LDMOS transistor according to first comparative example. The semiconductor device of the first comparative example is a lateral MOSFET having a source region SR and a drain region DR in the upper surface of the semiconductor substrate SB, and is an LDMOS including an element isolation region STI under the gate electrode GE. The semiconductor substrate SB has an n-type semiconductor region NR1 having a predetermined depth from an upper surface. In the semiconductor region NR1, a p-type well PW and an n-type well NW each having a predetermined depth from the upper surface of the semiconductor region NR1 are formed so as to be spaced apart from each other. A p-type body layer PB is formed in the p-type well, and a p-type contact region BC and an n-type source region SR are formed in an upper surface of the body layer PB (upper surface of the semiconductor substrate SB). An n-type drain region is formed in an upper surface of the n-type well.

A gate electrode GE is formed on the semiconductor substrate SB between the source region SR and the drain region DR via a gate dielectric film GF. A trench is provided in the upper surface of the semiconductor substrate SB between the semiconductor region NR1 directly below the gate electrode GE and the drain region DR, and an element isolation region STI is embedded in the trench. An n-type drift layer DF is formed in the semiconductor region NR1 adjacent to the element isolation region STI.

In such LDMOS, when a high electric field is applied between the source and the drain, hot carriers are injected into the element isolation region STI and degradation occurs. That is, the hot carrier injection causes a circuit malfunction, an increase in power consumption, and a degradation in product life. That is, fixed charges (hot carriers) are trapped in the element isolation region STI, and depletion occurs from the trapped portion, so that the on-resistance of LDMOS increases.

As a countermeasure against this issue, it is conceivable to extend the length of the element isolation region STI. Further, as shown in the second comparative example in FIG. 34, it is conceivable to provide a silicon oxide film OX thicker than the gate dielectric film GF on the upper surface of the flat semiconductor substrate SB without forming the element isolation region STI, and to form a field plate electrode FP to which a gate potential is applied on the silicon oxide film OX. Here, the gate electrode GE and the field plate electrode FP are made of the same n-type polysilicon film. That is, the gate electrode GE and the field plate electrode FP are integrated with each other, and are both formed of an n-type polysilicon film.

However, in the above countermeasures, an interference of the potential at the interface between the silicon configuring the semiconductor substrate SB and the silicon oxide film OX is large, and the impact ionization rate is still large. Therefore, in each embodiment of the present application, an invention is made to solve the above-described room for improvement. Hereinafter, the technical idea in the present embodiment to which the present invention is applied will be described.

### First Embodiment

As a semiconductor device of the present embodiment, an LDMOS transistor (Laterally Diffused MOSFET) among MOSFET (Metal-Oxide-Semiconductor Field Effect Transistor) will be described.

### Structure of Semiconductor Device

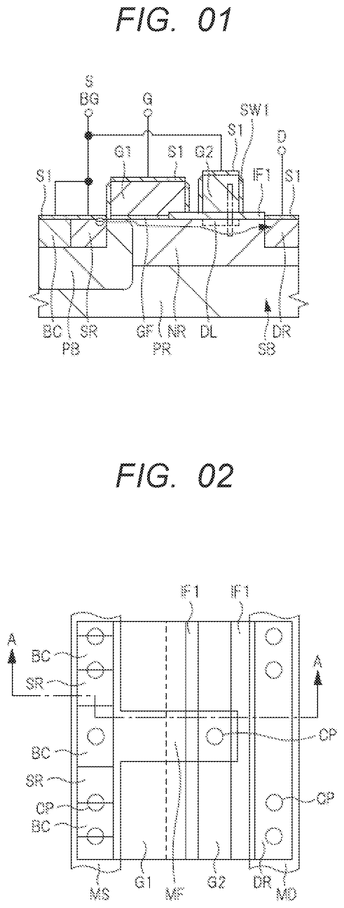

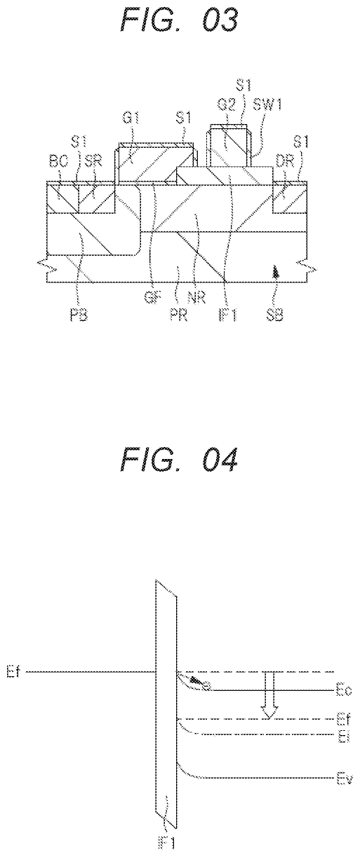

Hereinafter, the configuration of the semiconductor device of the present first embodiment will be described with reference to FIGS. 1 to 3. FIG. 1 is a cross-sectional view showing a main part of the semiconductor device according to the present embodiment. FIG. 2 is a plan view showing the semiconductor device according to the present embodiment. FIG. 3 is a cross-sectional view showing the semiconductor device of the present embodiment, which is cross-sectional view in A-A line of FIG. 2. The semiconductor device according to the present embodiment is a semiconductor device having an n-channel LDMOS transistor. The LDMOS transistor may be referred to as a lateral power MOSFET.

As shown in FIG. 1, the semiconductor device according to the present embodiment includes the semiconductor substrate SB made of silicon (Si) having the upper surface (first main surface) and an opposing lower surface (back surface, second main surface). In the semiconductor substrate SB, an n-type semiconductor region NR having a predetermined depth from the upper surface of the semiconductor substrate SB is formed. A p-type semiconductor region PR having a predetermined depth from the lower surface of the semiconductor region NR is formed in the semiconductor substrate SB. Although not shown, the semiconductor substrate SB may have an n-type semiconductor region under the semiconductor region PR. The semiconductor region NR is a low concentration region of the drain region and is an n-type drift region.

A p-type body layer PB having a predetermined depth from the upper surface of the semiconductor substrate SB is formed in the semiconductor substrate SB adjacent to the semiconductor region NR. In the body layer PB, a contact region BC which is a p-type semiconductor region (diffusion layer) having a predetermined depth from an upper surface of the body layer PB (upper surface of the semiconductor substrate SB) and a source region SR which is an n-type semiconductor region (diffusion layer) are formed adjacent to each other. The depth of the contact region BC and the depth of the source region SR are shallower than the depth of the semiconductor region NR. The contact region BC and the source region SR are spaced apart from each other with respect to the semiconductor region NR via the body layer PB in a direction (gate length direction) along the upper surface of the semiconductor substrate SB. In the semiconductor region NR, a drain region DR which is an n-type semiconductor region (diffusion layer) having a predetermined depth from the upper surface of the semiconductor region NR (upper surface of the semiconductor substrate SB) is formed. The drain region DR is spaced apart from the semiconductor region PR. The n-type impurity concentration of each of the source region SR and the drain region DR is larger than the n-type impurity concentration of the semiconductor region NR. The p-type impurity concentration of the contact region BC is larger than the p-type impurity concentration of the body layer PB.

A gate electrode G1 is formed on the semiconductor substrate SB between the source region SR and the drain region DR via the gate dielectric film GF. The gate electrode G1 is formed of an n-type semiconductor film, and is formed of, for example, a polysilicon film. A field plate electrode G2 is formed on the semiconductor substrate SB between a region directly below the gate dielectric film GF and the drain region DR via a dielectric film IF1 having a thickness larger than a thickness of the gate dielectric film GF. The gate dielectric film GF and the dielectric film IF1 are made of, for example, a silicon oxide film. The field plate electrode G2 is made of a p-type semiconductor film, for example, a polysilicon film. The gate electrode G1 and the field plate electrode G2 are spaced apart from each other directly above the dielectric film IF1. That is, a part of the gate electrode G1 is located directly above the gate dielectric film GF, and the other part is located directly above the dielectric film IF1. Sidewalls of the gate electrode G1 and the field plate electrode G2 are covered with sidewall spacers SW1.

The LDMOS that is the semiconductor device according to the present embodiment has at least the body layer PB, the source region SR, the drain region DR, and the gate electrode G1. The LDMOS according to the present embodiment further includes the dielectric film IF1, the field plate electrode G2, and the contact region BC. In the gate length direction of the LDMOS, a trench is formed in the upper surface of the semiconductor substrate SB in the regions adjacent to the source region SR and the drain region DR, which is opposite to the gate electrode G1 side, and the element isolation region is formed in the trench (not shown).

A silicide layer S1 is formed on the upper surface of the semiconductor substrate SB exposed from the gate dielectric film GF, the gate electrode G1, the dielectric film IF1, the field plate electrode G2, and the element isolation region. That is, the silicide layer S1 is formed in an upper surface of each of the source region SR, the contact region BC, and the drain region DR. In addition, the silicide layer S1 is also formed in each of an upper surface of the gate electrode G1 and an upper surface of the field plate electrode G2. In FIG. 1 and FIG. 3, among the structures above the silicide layer S1, the interlayer dielectric film, the contact plug, and the wiring layer are not shown. The silicide layer S1 serves to reduce the connection resistance between each of the source region SR, the contact region BC, the drain region DR, the gate electrode G1 and the field plate electrode G2, and the contact plug.

In FIG. 1, the source region SR and the contact region BC are arranged in the gate length direction, but in practice, as shown in FIG. 2, the source region SR and the contact region BC are alternately formed in the gate width direction of the LDMOS. In FIG. 2, the structure under the contact plug CP and the source wiring MS and the drain wiring MD on the contact plug CP is shown transparent. In FIG. 2, illustration of the silicide layer S1 and the interlayer dielectric film is omitted. Further, in FIG. 2, the outline of the terminal portion covered by the gate electrode G1 among the terminal portion of the dielectric film IF1 in the gate length direction is shown by a broken line.

As shown in FIG. 1 and FIG. 2, the source region SR and the contact region BC are electrically connected to the source wiring MS via the silicide layer S1 and the contact plug CP. The drain region DR is electrically connected to the drain wiring MD via the silicide layer S1 and the contact plug CP. In a region which is not shown, the gate electrode G1 is electrically connected to the gate wiring via the silicide layer S1 and the contact plug CP. Here, the field plate electrode G2 is electrically connected to the source wiring MS via the silicide layer S1 and the contact plug CP. That is, as shown in FIG. 2, a part of the source wiring MS extending in the gate width direction protrudes in the gate length direction and reaches a region directly above the field plate electrode G2. In this region, the source wiring MS and the field plate electrode G2 are electrically connected to each other.

Therefore, the source potential is supplied to the source region SR and the field plate electrode G2. Further, the gate potential is supplied to the gate electrode G1, and the drain potential is supplied to the drain region DR. The source potential (back gate potential) is supplied to the body layer PB via the contact region BC. However, the gate potential may be supplied to the field plate electrode G2 by electrically connecting the field plate electrode G2 to the gate wiring.

### Operation of Semiconductor Device

When the LDMOS according to the present embodiment is on-state, for example, the source region SR is supplied with 0 V, the drain region DR is supplied with 12 V, the gate electrode G1 is supplied with 5 V to 5.5 V, and the field plate electrode G2 is supplied with 0 V. As a result, the electrons flow from the source region SR through the vicinity of the upper surface of the semiconductor substrate SB to the drain region DR, as shown by arrows in FIG. 1. That is, the electrons move from the source region SR through the channel (inversion layer) formed in the upper surface of the body layer PB to the drain region DR through the vicinity of the upper surface of the semiconductor region NR. At this time, directly below the field plate electrode G2, a depletion layer DL having a thickness corresponding to the surface potential modulating region is formed in the semiconductor substrate SB in contact with the interface between the dielectric film IF1 and the semiconductor substrate SB. In FIG. 1, the depletion layer DL is outlined by a broken line.

Since a potential barrier is generated by the generation of the depletion layer DL, the electrons passing through the semiconductor region NR bypass the depletion layer DL and move toward the drain region DR. That is, the electrons pass through a portion away from the interface between the dielectric film IF1 and the semiconductor substrate SB. It will be described with reference to FIG. 4 to FIG. 7 that the electrons pass through the position away from the dielectric film IF1.

FIG. 4 is a band diagram showing the potential of electrons in LDMOS according to the present embodiment. Specifically, FIG. 4 is a band diagram of a part (field plate electrode part) extending over the field plate electrode G2, the dielectric film IF1, and the semiconductor region NR (semiconductor substrate SB) at a portion shown by a dashed-dotted line in FIG. 1. The dielectric film IF1 corresponds to the central portion of FIG. 4, and the left side of the dielectric film IF1 in FIG. 4 corresponds to the field plate electrode G2 and the right side of the dielectric film IF1 corresponds to the semiconductor region NR. FIG. 4 shows the Fermi level Ef, the Fermi level Ei of the intrinsic semiconductor, the valence band Ev, and the conduction band Ec.

Here, the potential of the field plate electrode G2 is 0 V, and the drain potential (positive potential) is supplied to the semiconductor region NR. Therefore, as shown in FIG. 4, the band is inclined so as to fall toward the semiconductor region NR. When the drain potential (positive potential) is supplied to the semiconductor region NR, as shown by the white arrow in FIG. 4, the Fermi level is lower in the semiconductor region NR than in the field plate electrode G2. In addition, in the semiconductor region NR in the vicinity of the dielectric film IF1, the depletion layer DL is generated, so that the band is bent and a repulsive force is generated against electrons. Note that the potential supplied to the field plate electrode G2 may be a low potential, but the feedback capacitance may be reduced if it is 0 V. Therefore, operation of LDMOS can be accelerated with less switching loss. Further, when the gate potential is supplied to the field plate electrode G2, electric field relaxation, breakdown voltage improvement, and on-resistance reduction can be realized.

Here, by forming the field plate electrode G2 and supplying the source potential or the gate potential, the drain breakdown voltage of the end portion of the gate electrode on drain side can be improved. That is, BVDSS (breakdown voltage between drain and source) at the time of LDMOS being turned off is prevented from decreasing. Further, by forming the field plate electrode G2 and supplying the source potential or the gate potential, the interface between the semiconductor substrate SB and the dielectric film IF1, that is, the vicinity of the interface between S1 and SiO is depleted by potential modulation. This depletion allows the electron current to flow away from the interface in the semiconductor substrate SB and avoid concentration of electrons on the surface of the semiconductor substrate SB. Therefore, it is possible to prevent the presence of electrons, which are candidates for hot carriers, in the vicinity of the surface of the semiconductor substrate SB where the electric field is strong, hot carrier injection resistance can be improved.

Here, the present inventors have experimentally found that when a material having a low work function with respect to low concentration n-type silicon (semiconductor region NR) formed under the dielectric film IF1 is used for the field plate electrode G2, the improvement effect for the hot carrier injection is not sufficient. Therefore, as one of the main features of the present embodiment, a p-type silicon film is used for the field plate electrode G2 as a material having a larger work function than the semiconductor region NR formed under the dielectric film IF1.

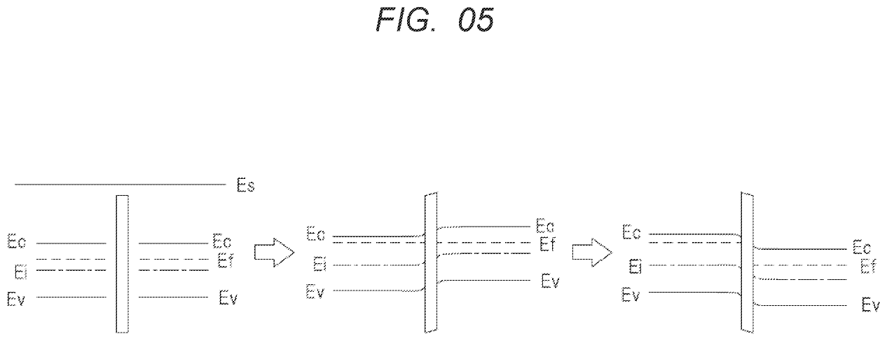

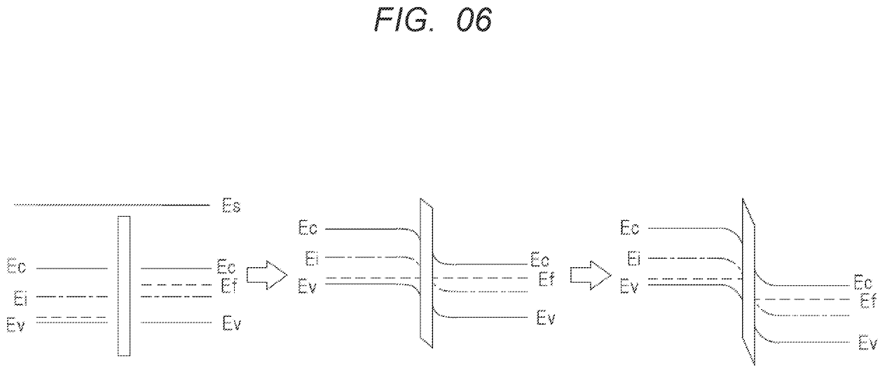

FIG. 5 shows the modulation of the potential in the vicinity of the n-type field plate electrode by a band diagram, and FIG. 6 shows the modulation of the potential in the vicinity of the p-type field plate electrode by a band diagram. In FIG. 5 and FIG. 6, three band diagrams are arranged to show the transition of the band structure from left to right. In the same manner as in FIG. 4, the band diagrams show the band structure over the field plate electrode, the dielectric film, and the semiconductor substrate (n-type semiconductor region, n-type drift region). In FIG. 5 and FIG. 6, the Fermi level Ef is shown by a dashed line, and the Fermi level Ei of the intrinsic semiconductor is shown by a dashed-dotted line.

On the left side of FIG. 5 and FIG. 6, a band diagram before the junction of the field plate electrode and the n-type drift region (corresponding to the semiconductor region NR) is shown. In the middle of FIG. 5 and FIG. 6, there is shown a band diagram of the equilibrium state after the junction of the field plate electrode and the n-type drift region and in the zero bias, which is there is no potential difference between them. On the right side of FIG. 5 and FIG. 6, a band diagram is shown in which a positive potential (drain voltage) is supplied to the n-type drift region after the junction between the field plate electrode and the n-type drift region. On the left side of band diagrams of FIG. 5 and FIG. 6, a vacuum level Es is shown above. The vacuum level Es is 0.95 eV. The n-type impurity concentration of the n-type drift region is 1×10¹⁷ cm⁻³.

The field plate electrode shown in FIG. 5 is made of an n-type polysilicon film, and its work function Φs is about 4.10 eV prior to junction (the left side of FIG. 5). The field plate electrode shown in FIG. 6 is made of a p-type polysilicon film, and its work function Φs is about 5.10 eV prior to junction (the left side of FIG. 6). Before junction (the band diagrams on the left side in FIG. 5 and FIG. 6), the work function Φs of the n-type drift region is about 4.20 eV.

As shown in the middle band diagram of FIG. 5 and FIG. 6, in the equilibrium state after junction, when the field plate electrode is n-type, the band is inclined so as to rise on the n-type drift region side, and when the field plate electrode is p-type, the band is inclined so as to fall on the n-type drift region side. As shown in the middle band diagrams of FIG. 5 and FIG. 6, in a state in which a drain voltage is supplied to the n-type drift region, the band structure transitions so that the band falls on the n-type drift region side, regardless of whether the field plate electrode is n-type or p-type. Here, it can be seen that the bending of the band is larger in the case of the p-type field plate electrode than in the case of the n-type field plate electrode, and the potential modulation is larger in the n-type drift region in the vicinity of the dielectric film. That is, when a p-type field plate electrode having a work function larger than that of the n-type drift region is provided, a larger repulsive force acts on electrons in the n-type drift region in the vicinity of the dielectric film than in the case where the field plate electrode is of the n-type. As described above, since the work function of the field plate electrode is large, the band bending (surface potential modulation) in the n-type drift region becomes large, and the concentration of electrons at interface can be more effectively relaxed. This was confirmed by experiments by the present inventors.

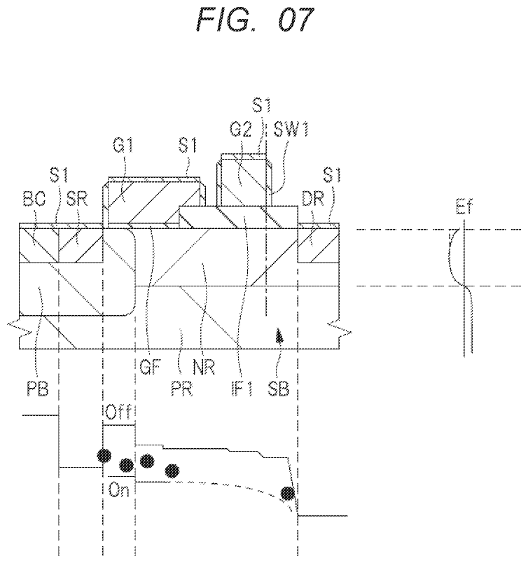

FIG. 7 shows a cross-sectional view of the semiconductor device in a LDMOS with a p-type field plate electrode G2 and a graph of the potential corresponding to the position of cross-sectional view. In the graph under the cross-sectional view of FIG. 7, the potential, i.e., the electron energy, increases from the upper side to the bottom. In the graph to the right of the cross-sectional view in FIG. 7, the potential, i.e., the electron energy, increases from the right side to the left side. In the graph under the cross-sectional view of FIG. 7, the electrons are schematically shown by black circles, and the off-state potential (solid line) and the on-state potential (solid line and broken line) of LDMOS are shown. The graph to the right of the cross-sectional view in FIG. 7 shows the potential at a position shown by a dashed-dotted line in cross-sectional view in FIG. 7, that is, at a position overlapping with the drain-side end portion of the field plate electrode G2 in plan view.

As shown in the graph under the cross-sectional view of FIG. 7, since the potential directly below the gate electrode G1 is low in the off-state, the electrons of the source region SR do not flow toward the drain region DR. On the other hand, in the on-state, since the potential directly below the gate electrode G1 increases, the electrons of the source region SR flow toward the drain region DR.

As shown in the graph to the right of the cross-sectional view of FIG. 7, in the semiconductor region NR under the field plate electrode G2, the potential is modulated in accordance with the magnitude of the work function of the field plate electrode G2 in the vicinity of the dielectric film IF1, and the Fermi level decreases toward the lower potential. Thus, the potential drop at the surface of the semiconductor substrate SB under the field plate electrode G2 generates a repulsive force on the electrons and prevents the electrons from passing through the surface.

Here, the p-type silicon is exemplified as the material of the field plate electrode G2, but the material of the field plate electrode G2 is not limited thereto. The material of the field plate electrode G2 may be any material having a higher work function than the semiconductor region NR. The field plate electrode G2 may be made of copper (Cu) or platinum (Pt), for example. The work function of copper is 5.10 eV, and the work function of platinum is 5.64 eV. The work function of the p-type field plate electrode G2 depends on the impurity concentration, but is, for example, 5.14 eV. The work function of the semiconductor region NR is, for example, 4.20 eV.

When the conductivity type of the field plate electrode G2 is n-type, the work function is, for example, 4.08 eV and is smaller than the work function of the semiconductor region NR. Therefore, when the field plate electrode G2 is n-type, the hot carrier injection resistance is insufficient. Therefore, from the viewpoint of enhancing the hot carrier injection resistance, it is not preferable to use n-type semiconductor as the material of the field plate electrode G2.

In the present embodiment, the n-type gate electrode G1 and the p-type field plate electrode G2 are described as a semiconductor film, but these electrodes have a sufficiently high impurity concentration and a low resistivity, and therefore can be referred to as a conductive film.

### Method of Manufacturing Semiconductor Device

A method of manufacturing the semiconductor device according to the present embodiment will be described with reference to FIG. 8 to FIG. 14.

First, as shown in FIG. 8, the semiconductor substrate SB made of monocrystalline silicon is prepared. Subsequently, n-type impurities (for example, phosphorus (P)) are implanted into a shallow region relatively close to the upper surface of the semiconductor substrate SB by an ion implantation method. P-type impurities (for example, boron (B)) are implanted into a relatively deep region of the semiconductor substrate SB by an ion implantation method. Thus, in the semiconductor substrate SB, an n-type semiconductor region NR in contact with the upper surface of the semiconductor substrate SB and a p-type semiconductor region PR in contact with the lower surface of the semiconductor region NR are formed. Subsequently, in order to activate the semiconductor regions NR, PR, the semiconductor substrate SB is subjected to a heat treatment.

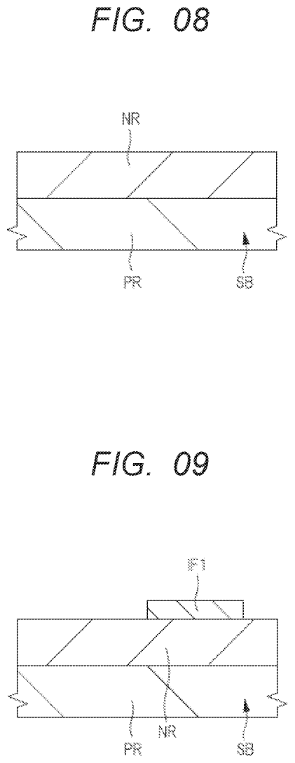

Next, as shown in FIG. 9, a dielectric film IF1 made of a silicon oxide film is formed on the upper surface of the semiconductor substrate SB by, for example, CVD (Chemical Vapor Deposition) method. Subsequently, the dielectric film IF1 is patterned (processed) using a photolithography technique and a dry etching method. This exposes a part of the upper surface of the semiconductor substrate SB.

Next, as shown in FIG. 10, the exposed upper surface of the semiconductor substrate SB is oxidized using an oxidation method. Thus, a silicon oxide film is formed. Subsequently, a polysilicon film (semiconductor film) is formed on the silicon oxide film and the dielectric film IF1 by, for example, a CVD method. Subsequently, the polysilicon film and the silicon oxide film are patterned (processed) using a photolithography technique and a dry etching method. As a result, a part of the upper surface of the semiconductor substrate SB and a part of the upper surface of the dielectric film IF1 are exposed. Further, a gate electrode G1 and a field plate electrode G2 made of the polysilicon film are formed to be spaced apart from each other, and the gate dielectric film GF made of the silicon oxide film is formed. The gate electrode G1 is formed on the upper surface of the semiconductor substrate SB and the upper surface of the dielectric film IF1. In a direction (gate length direction) in which the gate electrode G1 and the field plate electrode G2 are next to each other, both ends of the field plate electrode G2 are terminated directly above the dielectric film IF1.

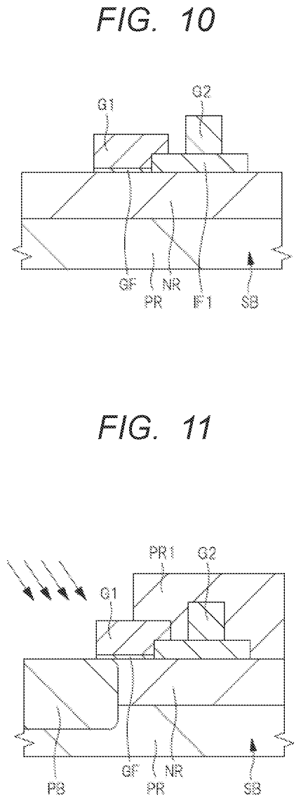

Next, as shown in FIG. 11, the body layer PB, which is a p-type semiconductor region, is formed in the semiconductor substrate SB. Here, the body layer PB is formed by implanting p-type impurities (for example, boron (B)) into the semiconductor substrate SB by an ion implantation method using a photoresist film PR1 as a mask. The photoresist film PR1 covers, for example, a part of the upper surface of the gate electrode G1, the dielectric film IF1 and the field plate electrode G2, and covers the upper surface of the semiconductor substrate SB exposed from the dielectric film IF1 in the upper surface facing away from the gate electrode G1. In other words, the photoresist film PR1 exposes the upper surface opposite to the dielectric film IF1 among the upper surface of the semiconductor substrate SB exposed from the gate electrode G1. In the step of implanting the p-type impurities, oblique ion implantation is performed. By performing oblique ion implantation, a part of the body layer PB can be formed directly below the gate electrode G1. The body layer PB is formed from the upper surface of the semiconductor substrate SB to a predetermined depth of the semiconductor region PR.

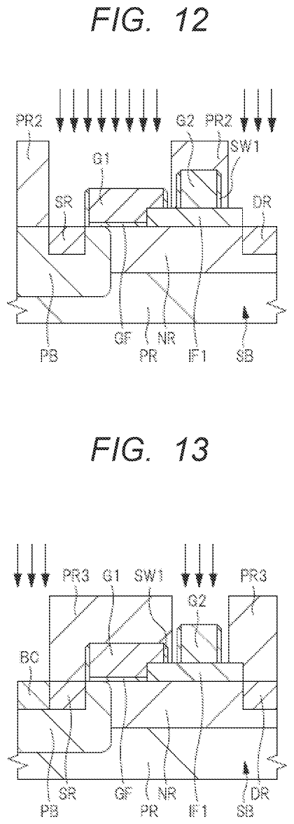

Next, as shown in FIG. 12, after the photoresist film PR1 is removed, sidewall spacers SW1 are formed to cover the sidewalls of the gate electrode G1 and the field plate electrode G2. The sidewall spacer SW1 is formed, for example, by depositing a dielectric film made of a silicon oxide film or the like on the semiconductor substrate SB by a CVD method and then performing etch-back to expose the upper surface of each of the semiconductor substrate SB, the gate electrode G1, and the field plate electrode G2. Subsequently, n-type impurities (for example, phosphorus (P) or arsenic (As)) are implanted into the upper surface of the semiconductor substrate SB in a region next to a structure including the gate electrode G1 and the dielectric film IF1 in the gate length direction and the gate electrode G1 by an ion implantation method. In this way, an n-type source region SR and an n-type drain region DR are formed in the semiconductor substrate SB so as to sandwich the structure. Here, ion implantation is performed using a photoresist film PR2 that covers a part of the upper surface of the body layer PB and the entire field plate electrode G2 and exposes the gate electrode G1 and the semiconductor substrate SB that is next to each other in the gate length direction. Therefore, the gate electrode G1 is an n-type semiconductor film, but the n-type impurities are not implanted into the field plate electrode G2.

Next, as shown in FIG. 13, after the photoresist film PR2 is removed, a part of the upper surface of the body layer PB and the field plate electrode G2 are exposed, and a photoresist film PR3 covering the gate electrode G1, the source region SR, and the drain region DR is formed. Subsequently, p-type impurities (for example, boron (B)) are implanted into the upper surface of the semiconductor substrate SB (the upper surface of the body layer PB) and the field plate electrode G2. Accordingly, a p-type contact region BC adjacent to the source region SR is formed in the upper surface of the semiconductor substrate SB (the upper surface of the body layer PB). In addition, the field plate electrode FP is formed as a p-type semiconductor film by the ion implantation process. Although the gate electrode G1 and the field plate electrode G2 are originally the same polysilicon film, the different conductivity types of the semiconductor films are obtained by performing the separation of the ion species described with reference to FIG. 12 and FIG. 13. Note that the process described with reference to FIG. 13 may be performed before the process described with reference to FIG. 12.

Through the above steps, the LDMOS including at least the body layer PB, the source region SR, the drain region DR, and the gate electrode G1 is formed. The LDMOS according to the present embodiment further includes the dielectric film IF1, the field plate electrode G2, and the contact region BC.

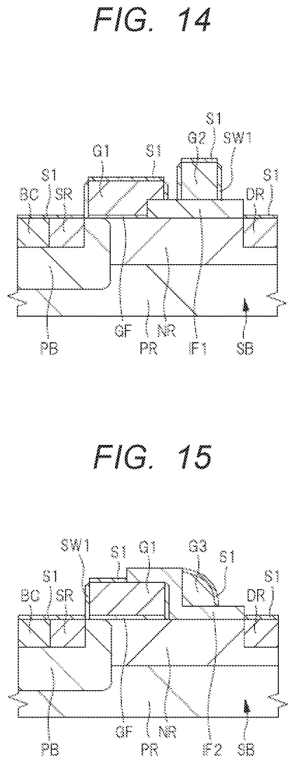

Next, as shown in FIG. 14, after the photoresist film PR3 is removed, a well-known salicide process is performed to form silicide layer S1 in an upper surface of each of the contact region BC, the source region SR, the drain region DR, the gate electrode G1, and the field plate electrode G2. The silicide layer S1 is made of, for example, nickel-silicon (NiSi). The sidewall spacer SW1 serves as a silicide block film.

Thereafter, although not shown, an interlayer dielectric film, a contact plug, and a wiring layer are formed on the LDMOS, the semiconductor substrate SB, and the silicide layer S1, thereby substantially completing the semiconductor device according to the present embodiment.

### Effects of Present Embodiment

In the present embodiment, the drain breakdown voltage of the end portion of the drain-side gate electrode can be improved by forming the field plate electrode G2 and applying the source potential or the gate potential to the field plate electrode G2. That is, a field plate effect is obtained.

In addition, by setting the distance between the gate electrode G1 and the field plate electrode G2 to the smallest lithography rule, the distance between the electrodes is made as small as possible. As a result, the electric field in the semiconductor substrate SB under the electrodes can be relaxed, and the capacitance between gate-drain can be reduced.

Further, by applying a source potential or a gate potential to the field plate electrode G2, the vicinity of the interface between the semiconductor substrate SB and the dielectric film IF1 is depleted by potential modulation. As a result, the electronic current flows apart from the interface in the semiconductor substrate SB, so that the hot carrier injection resistance can be improved. That is, the potential modulation effect by the field plate electrode relaxes the interference of the potential of the interface, thereby suppressing the occurrence of hot carrier injection. In the present embodiment, since the field plate electrode G2 is made of a material having a large work function with respect to the semiconductor region NR located under the dielectric film IF1, the improvement effect for the hot carrier injection can be effectively obtained.

In addition, in the method of manufacturing the semiconductor device according to the present embodiment, a polysilicon film may be formed in one layer in order to form the gate electrode G1 and the field plate electrode G2, and the step of forming the polysilicon film may be minimized.

As described above, in the present embodiment, it is possible to realize a LDMOS having a high breakdown voltage and a high hot carrier injection resistance. That is, the performance of the semiconductor device can be improved.

### Second Embodiment

### Structure of Semiconductor Device

The structure of the semiconductor device according to the present second embodiment will be described below with reference to FIG. 15. FIG. 15 is a cross-sectional view showing the semiconductor device according to the present embodiment.

As shown in FIG. 15, the structure in the semiconductor substrate SB, the structure of the gate dielectric film GF and the gate electrode G1 of LDMOS according to the present embodiment are the same as those of the first embodiment. On the other hand, the entire gate electrode G1 is formed on the gate dielectric film GF, which differs from the first embodiment. That is, a part of the gate electrode G1 is not arranged on the dielectric film thicker than the gate dielectric film GF. The dielectric film IF2 interposed between the semiconductor substrate SB and the field plate electrode G3 covers the entire side surface of the gate electrode G1 and a part of the upper surface of the gate electrode G1, which differs from the first embodiment. Further, the field plate electrode G3 is formed in a sidewall spacer shape on the side surface of the dielectric film IF2 covering the side surface of the gate electrode G1, which differs from the first embodiment.

Here, the dielectric film IF2 is continuously formed from directly above the upper surface of the gate electrode G1 to directly above the boundary between the semiconductor region NR and the drain region DR in the gate length direction, and exposes a part of the upper surface of the gate electrode G1 and the upper surface of the drain region DR. That is, the dielectric film IF2 continuously covers a part of the upper surface of the gate electrode G1, the side surface of the gate electrode G1, and the upper surface of the semiconductor substrate SB between the gate electrode G1 and the drain region DR. The dielectric film IF2 is formed using a silicide block oxide film having a larger film thickness than the gate dielectric film GF.

The field plate electrode G3 made of a p-type polysilicon film is formed next to the side surface of the gate electrode G1 via the dielectric film IF2 in the gate length direction. In the gate length direction, the field plate electrode G3 and the drain region DR are spaced apart from each other.

### Method of Manufacturing Semiconductor Device

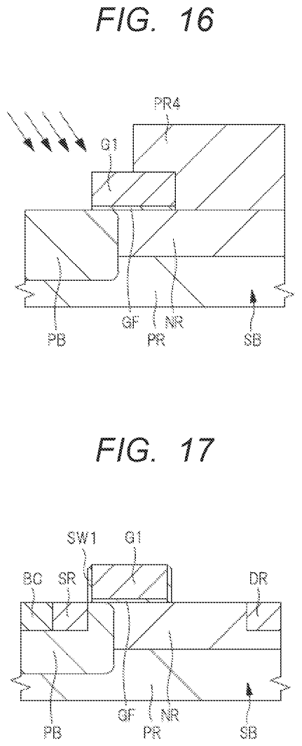

A method of manufacturing the semiconductor device according to the present embodiment will be described with reference to FIG. 16 to FIG. 21.

First, as shown in FIG. 16, the semiconductor substrate SB including semiconductor regions NR, PR is prepared by performing a step similar to the process described with reference to FIG. 8. Subsequently, the exposed upper surface of the semiconductor substrate SB is oxidized. Thus, a silicon oxide film is formed. Subsequently, a polysilicon film (semiconductor film) is formed on the silicon oxide film by, for example, a CVD method. Subsequently, the polysilicon film and the silicon oxide film are patterned (processed) using a photolithography technique and a dry etching method. This exposes a part of the upper surface of the semiconductor substrate SB. Further, a gate electrode G1 made of the polysilicon film and a gate dielectric film GF made of the silicon oxide film are formed.

Subsequently, a photoresist film PR4 is formed which exposes, in the gate length direction, the upper surface of semiconductor substrate SB on one side of the gate electrode G1 and covers the upper surface of the other semiconductor substrate SB on the other side. Subsequently, p-type impurities (for example, boron (B)) are implanted into the semiconductor substrate SB by an ion implantation method using the photoresist film PR4 as a mask. Accordingly, the body layer PB which is a p-type semiconductor region is formed in the semiconductor substrate SB. In the step of implanting the p-type impurities, a part of the body layer PB can be formed directly below the gate electrode G1 by performing oblique ion implantation. The body layer PB has a predetermined depth from the upper surface of the semiconductor substrate SB.

Next, as shown in FIG. 17, after the photoresist film PR4 is removed, sidewall spacers SW1 covering the sidewalls of the gate electrode G1 are formed, followed by forming a contact region BC, a source region SR, and a drain region DR. The step of forming the diffusion layers is the same as the step described with reference to FIG. 12 and FIG. 13, except that the dielectric film IF1 and the field plate electrode G2 do not exist. That is, in the step of forming the source region SR and the drain region DR, n-type impurities are also implanted into the gate electrode G1, and in the step of forming the contact region BC, p-type impurities is not implanted into the semiconductor film on the semiconductor substrate SB.

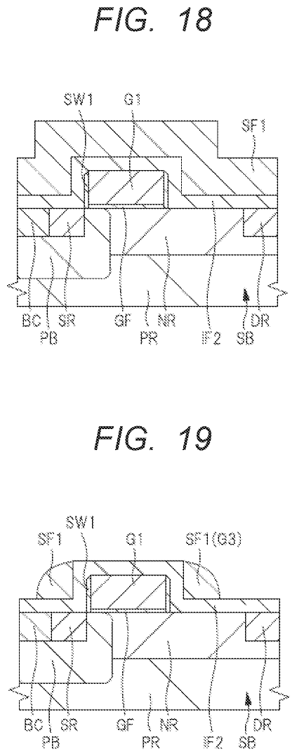

Next, as shown in FIG. 18, a dielectric film IF2 made of a silicon oxide film is formed (deposited) on the upper surface of the semiconductor substrate SB by, for example, a CVD method. Subsequently, a polysilicon film (silicon film, semiconductor film) SF1 is formed on the dielectric film IF2 by, for example, a CVD method. The polysilicon film SF1 is a p-type semiconductor film formed by implanting p-type impurities (for example, boron (B)) at the time of film formation. Since the thickness of the dielectric film IF2 is smaller than the thickness of the gate electrode G1, the polysilicon film SF1 is formed next to the side surface of the gate electrode G1 via the dielectric film IF2.

Next, as shown in FIG. 19, an upper surface of the dielectric film IF2 is exposed by etching back the polysilicon film SF1. As a result, the polysilicon film SF1 remains in the sidewall spacer shape only at a position covering the side surface of the gate electrode G1 via the dielectric film IF2. The polysilicon film SF1 covering the side surface of the gate electrode G1 on the drain region DR side configures the field plate electrode G3.

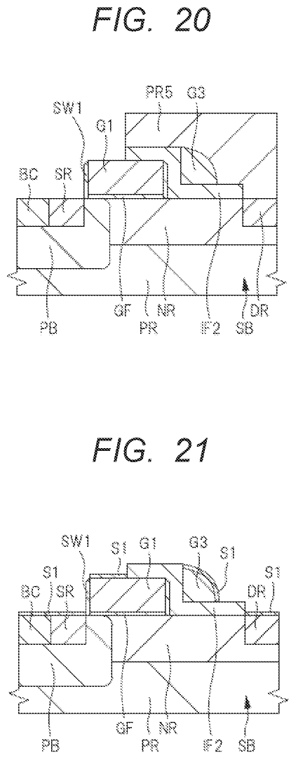

Next, as shown in FIG. 20, a photoresist film (not shown) which exposes, in the gate length direction, the upper surface of the semiconductor substrate SB on the source region SR side of the gate electrode G1 and covers the upper surface of the semiconductor substrate SB on the drain region DR side of the gate electrode G1 and the field plate electrode G3 is formed. Subsequently, the polysilicon film SF1 next to the side surface of the gate electrode G1 on the source region SR side is removed by a dry etching method or a wet etching method using the photoresist film as a mask.

Subsequently, after the photoresist film is removed, a dielectric film IF2 is formed to cover the source region SR, the contact region BC, the drain region DR, and a part of the upper surface of the gate electrode G1. Subsequently, a photoresist film PR5 covering the field plate electrode G3 is formed. Subsequently, dry etching is performed using the photoresist film PR5 as a mask to expose a part of the upper surface of the gate electrode G1, the upper surface of each of the source region SR, the contact region BC, and the drain region DR from the dielectric film IF2. Although not shown, a part of the dielectric film IF2 may be left as a sidewall spacer so as to cover the side surface of the gate electrode G1 on the source region SR side.

Through the above steps, the LDMOS including at least the body layer PB, the source region SR, the drain region DR, and the gate electrode G1 is formed. The LDMOS according to the present embodiment further includes a dielectric film IF2, a field plate electrode G3, and a contact region BC.

Next, as shown in FIG. 21, by performing a well-known salicide process, a silicide layer S1 is formed in an upper surface of each of the contact region BC, the source region SR, the drain region DR, the gate electrode G1, and the field plate electrode G3. The dielectric film IF2 serves as a silicide block film that prevents a part of the upper surface of the semiconductor substrate SB and the side surface of the gate electrode G1 on the drain region DR side from being silicided. As a result of the silicide process, a silicide layer S1 is formed on the field plate electrode G3 so as to cover the upper surface and the side surface on the drain region DR side.

Thereafter, although not shown, an interlayer dielectric film, a contact plug, and a wiring layer are formed on the LDMOS, the semiconductor substrate SB, and the silicide layer S1, thereby substantially completing the semiconductor device according to the present embodiment.

### Effects of Present Embodiment

In the present embodiment, the drain breakdown voltage of the end portion of the drain-side gate electrode can be improved by applying a source potential or a gate potential to the field plate electrode G3 provided separately from the gate electrode G1 in the LDMOS.

The distance between the gate electrode G1 and the field plate electrode G3 is determined by the thickness of the dielectric film IF2. Therefore, the distance can be set to be equal to or less than the minimum rule of lithography, and the distance can be set to an optimum distance for securing the breakdown voltage. In addition, when the distance is determined by the accuracy of the lithography technique, the distance may vary due to a positional deviation of the lithography. On the other hand, the present embodiment can control the distance with higher accuracy. Therefore, since the field plate electrode G3 and the gate electrode G1 can be formed closer to each other, the electric field in the semiconductor substrate SB in the vicinity of the end portion of the gate electrode G1 can be relaxed and the capacitance between gate-drain can be reduced compared with the first embodiment.

Further, by applying a source potential or a gate potential to the field plate electrode G3, the vicinity of the interface between the semiconductor substrate SB and the dielectric film IF2 is depleted by potential modulation. This allows the current to flow apart from the interface in the semiconductor substrate SB, thereby improving hot carrier injection resistance. In the present embodiment, since the field plate electrode G3 is made of a material having a large work function with respect to the semiconductor region NR located under the dielectric film IF2, the improvement effect for the hot carrier injection can be effectively obtained.

As described above, in the present embodiment, it is possible to realize the LDMOS having a high breakdown voltage and a high hot carrier injection resistance. That is, the performance of the semiconductor device can be improved.

### Third Embodiment

### Structure of Semiconductor Device

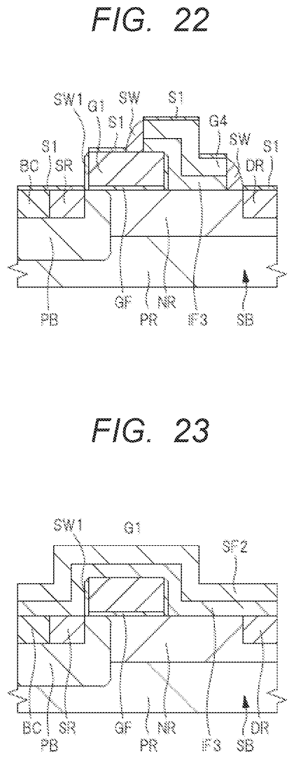

The structure of the semiconductor device according to the present third embodiment will be described below with reference to FIG. 22. FIG. 22 is a cross-sectional view showing the semiconductor device according to the present embodiment.

As shown in FIG. 22, the structure in the semiconductor substrate SB, the structure of the gate dielectric film GF and the gate electrode G1 of the LDMOS according to the present embodiment are the same as those of the first embodiment. On the other hand, the entire gate electrode G1 is formed on the gate dielectric film GF, which differs from the first embodiment described above. That is, the gate electrode G1 is not formed on the dielectric film thicker than the gate dielectric film GF. The dielectric film IF3 interposed between the semiconductor substrate SB and the field plate electrode G4 covers the entire side surface of the gate electrode G1 and the upper surface of the gate electrode G1, which differs from the first embodiment described above. The upper surface of the semiconductor substrate SB (semiconductor region NR) between the dielectric film IF3 and the drain region DR is covered with a sidewall spacer SW made of a silicon oxide film in the gate length direction, which differs from the second embodiment described above. Further, the field plate electrode G4 continuously covers the upper surface and the side surface of the gate electrode G1 via the dielectric film IF3, which differs from the first embodiment and the second embodiment described above.

Here, the dielectric film IF3 is continuously formed from the upper surface of the gate electrode G1 to a part of the upper surface of the semiconductor region NR between the gate electrode G1 and the drain region DR in the gate length direction. The dielectric film IF3 exposes a part of the upper surface of the gate electrode G1, the upper surface of the drain region DR, and the upper surface of the semiconductor region NR adjacent to the side surface of the gate electrode G1 on the source region SR side. That is, the dielectric film IF3 continuously covers a part of the upper surface of the gate electrode G1, a side surface of the gate electrode G1, and a part of the upper surface of the semiconductor substrate SB between the gate electrode G1 and the drain region DR. The dielectric film IF3 is formed using a silicide block oxide film having a larger film thickness than the gate dielectric film GF.

The field plate electrode G4 is continuously formed in contact with the upper surface of the dielectric film IF3 located between the gate electrode G1 and the drain region DR in the gate length direction, the side surface on the drain region DR side among the side surface of the dielectric film IF3 covering the side surface of the gate electrode G1 on the drain region DR side, the upper surface of the dielectric film IF3 on the upper surface of the gate electrode G1. That is, the laminated film formed of the dielectric film IF3 and the field plate electrode G4 continuously covers the upper surface of the semiconductor substrate SB between the gate electrode G1 and the drain region DR, the side surface of the gate electrode G1 on the drain region DR side, and a part of the upper surface of the gate electrode G1.

A part of the field plate electrode G4 made of a p-type polysilicon film is formed next to the side surface of the gate electrode G1 via the dielectric film IF3 in the gate length direction. In the gate length direction, the field plate electrode G4 and the drain region DR are spaced apart from each other because the sidewall spacer SW is formed therebetween. The sidewall spacer SW covers a side surface on the drain region DR side of the laminated film formed of the dielectric film IF3 and the field plate electrode G4. The sidewall spacer SW exposes the upper surface of the drain region DR.

In addition, directly above the gate electrode G1, the side surface (termination surface) of the laminated film is covered with other sidewall spacer SW. A part of the upper surface of the gate electrode G1 is exposed from the laminated film and the sidewall spacer SW, and is covered with the silicide layer S1.

### Method of Manufacturing Semiconductor Device

The method of manufacturing the semiconductor device according to the present embodiment will be described with reference to FIG. 23 to FIG. 26.

First, as shown in FIG. 23, the same steps as those described with reference to FIG. 16 and FIG. 17 are performed. As a result, the semiconductor regions NR, PR, the source region SR, the contact region BC, and the drain region DR are formed in the semiconductor substrate SB, and the gate electrode G1 is formed on the semiconductor substrate SB via the gate dielectric film GF.

Subsequently, a dielectric film IF3 made of a silicon oxide film is formed (deposited) on the upper surface of the semiconductor substrate SB by, for example, a CVD method. Subsequently, a polysilicon film (silicon film, semiconductor film) SF2 is formed on the dielectric film IF3 by, for example, a CVD method. The polysilicon film SF2 is a p-type semiconductor film formed by implanting p-type impurities (for example, boron (B)) at the time of film formation. Since the film thickness of the dielectric film IF3 is smaller than the film thickness of the gate electrode G1, the polysilicon film SF2 is formed on the side surface of the gate electrode G1 via the dielectric film IF3 next to the gate electrode G1. The film thickness of the polysilicon film SF2 is smaller than the film thickness of the polysilicon film SF1 described in the second embodiment described above.

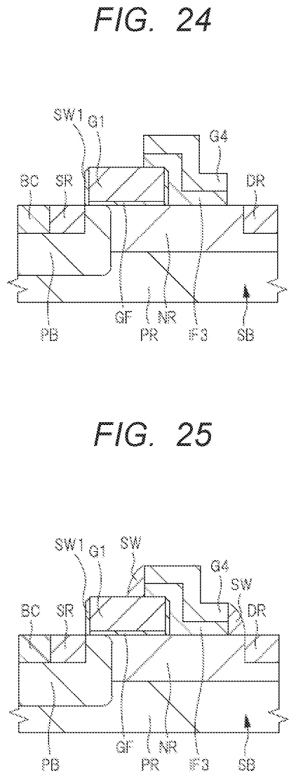

Next, as shown in FIG. 24, a laminated film formed of a dielectric film IF3 and a polysilicon film SF2 is patterned by a photolithography technique and a dry etching method. As a result, the upper surface of the semiconductor substrate SB including the upper surface of each of the source region SR, the contact region BC, and the drain region DR and the upper surface of the gate electrode G1 are exposed. The polysilicon film SF2 configures a field plate electrode G4.

Next, as shown in FIG. 25, a silicon oxide film is formed (deposited) on the upper surface of the semiconductor substrate SB by, for example, a CVD method. As a result, the upper surface of the semiconductor substrate SB, the upper surface and the side surface of the gate electrode G1, and an upper surface and a side surface of the laminated film formed of the dielectric film IF3 and the field plate electrode G4 are covered with the silicon oxide film. Subsequently, a part of the silicon oxide film is removed by a dry etching method or a wet etching method. As a result, a part of the upper surface of the gate electrode G1 and the upper surface of the semiconductor substrate SB including the upper surface of each of the source region SR, the contact region BC, and the drain region DR are exposed. By this etching step, the silicon oxide film covering each of the side surfaces on both sides of the laminated film in the gate length direction is left as a sidewall spacer SW. Although not shown in FIG. 25, the silicon oxide film covering the side surface of the gate electrode G1 on the source region SR side may be left in a sidewall spacer shape.

Through the above steps, the LDMOS including at least the body layer PB, the source region SR, the drain region DR, and the gate electrode G1 is formed. The LDMOS according to the present embodiment further includes a dielectric film IF3, a field plate electrode G4, and a contact region BC.

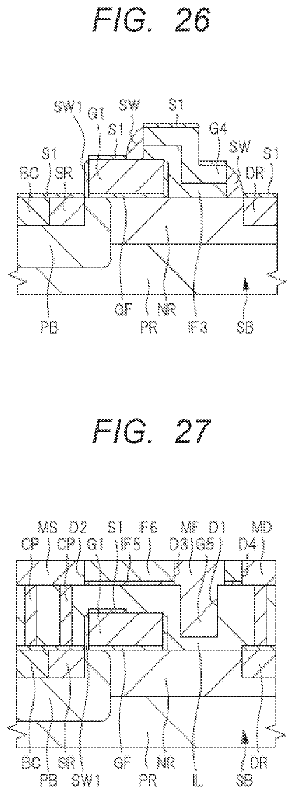

Next, as shown in FIG. 26, by performing a well-known salicide process, a silicide layer S1 is formed on an upper surface of each of the exposed contact region BC, source region SR, drain region DR, gate electrode G1 and field plate electrode G4. The dielectric film IF3 serves as a silicide block film that prevents the upper surface of a part of the semiconductor substrate SB and the side surface of the gate electrode G1 on the drain region DR side from being silicided.

Thereafter, although not shown, an interlayer dielectric film, a contact plug, and a wiring layer are formed on the LDMOS, the semiconductor substrate SB, and the silicide layer S1, thereby substantially completing the semiconductor device according to the present embodiment.

### Effects of Present Embodiment

In the present embodiment, the drain breakdown voltage of the end portion of the drain-side gate electrode can be improved by supplying a source potential or a gate potential to the field plate electrode G4 provided apart from the gate electrode G1 in the LDMOS.

The distance between the gate electrode G1 and the field plate electrode G4 is determined by the thickness of the dielectric film IF3. Therefore, the distance can be set to be equal to or less than the minimum rule of lithography, and the distance can be set to an optimum distance for securing the breakdown voltage. In addition, when the distance is determined by the accuracy of the lithography technique, the distance may vary due to a positional deviation of the lithography or the like, but the distance can be controlled with a higher accuracy in the present embodiment. Therefore, since the field plate electrode G4 and the gate electrode G1 can be formed closer, it is possible to relax the electric field in the semiconductor substrate SB in the vicinity of the end portion of the gate electrode G1, and it is possible to reduce the capacitance between the gate-drain as compared with the first embodiment.

Further, by supplying a source potential or a gate potential to the field plate electrode G4, the vicinity of the interface between the semiconductor substrate SB and the dielectric film IF3 is depleted by potential modulation. This allows the current to flow apart from the interface in the semiconductor substrate SB, thereby improving hot carrier injection resistance. In the present embodiment, since the field plate electrode G4 is made of a material having a large work function with respect to the semiconductor region NR located under the dielectric film IF3, the improvement effect for the hot carrier injection can be effectively obtained.

As described above, in the present embodiment, it is possible to realize the LDMOS having a high breakdown voltage and a high hot carrier injection resistance. That is, the performance of the semiconductor device can be improved.

### Fourth Embodiment

### Structure of Semiconductor Device

Hereinafter, the structure of the semiconductor device according to the present fourth embodiment will be described with reference to FIG. 27. FIG. 27 is a cross-sectional view showing the semiconductor device according to the present embodiment.

As shown in FIG. 27, the structure in the semiconductor substrate SB, the structure of the gate dielectric film GF and the gate electrode G1 of the LDMOS according to the present embodiment are the same as those of the first embodiment. However, the entire gate electrode G1 is formed on the gate dielectric film GF. That is, the gate electrode G1 is not formed on the dielectric film thicker than the gate dielectric film GF. In addition, a dielectric film which is a silicide block film corresponding to the dielectric film IF2 of the second embodiment is formed, but in FIG. 27, the dielectric film is integrated with the interlayer dielectric film IL on the semiconductor substrate SB, and the outline of the dielectric film is not shown.

Here, an interlayer dielectric film IL covering the upper surface of the semiconductor substrate SB, the gate electrode G1 and the silicide layer S1 is formed. The interlayer dielectric film IL is mainly formed of, for example, a silicon oxide film. The upper surface of the interlayer dielectric film IL is planarized. In the gate length direction, a trench D1 is formed in the upper surface of the interlayer dielectric film IL between the gate electrode G1 and the drain region DR. A field plate electrode G5 formed of a conductive film is embedded in the trench D1.

The trench D1 does not penetrate the interlayer dielectric film IL and does not reach the upper surface of the semiconductor substrate SB. The shortest distance (distance in the thickness direction) between the bottom surface of the trench D1 and the upper surface of the semiconductor substrate SB is larger than the film thickness of the gate dielectric film GF. That is, the film thickness of the interlayer dielectric film IL directly below the field plate electrode G5 is larger than the film thickness of the gate dielectric film GF. In other words, the bottom surface of the field plate electrode G5 is located above the upper surface of the gate dielectric film GF. In the gate length direction, the field plate electrode G5 is next to the gate electrode G1 via a part of the interlayer dielectric film IL. That is, a part of the field plate electrode G5 is located at the same height as the gate electrode G1.

Although the structure on the interlayer dielectric film IL is not shown here, as described later in the method of manufacturing the semiconductor device, a wiring layer is formed on the interlayer dielectric film IL. The wiring layer includes a wiring electrically connected to each of the field plate electrode G5, the source region SR, the contact region BC, and the drain region DR. Although not shown here, the interlayer dielectric film IL has a plurality of contact holes that are through holes penetrating the interlayer dielectric film IL. Contact plugs (conductive connection part) are formed in the contact holes.

### Method of Manufacturing Semiconductor Device

A method of manufacturing the semiconductor device according to the present embodiment will be described with reference to FIG. 28 to FIG. 32.

First, as shown in FIG. 28, the same steps as those described with reference to FIG. 16 and FIG. 17 are performed. As a result, the semiconductor regions NR, PR, the source region SR, the contact region BC and the drain region DR are formed in the semiconductor substrate SB and the gate dielectric film GF and the gate electrode G1 are formed.

Subsequently, a dielectric film IF4 formed of a silicon oxide film is formed (deposited) on the upper surface of the semiconductor substrate SB by, for example, a CVD method. Subsequently, the dielectric film IF4 is patterned using a photolithography technique and a dry etching method. As a result, the upper surface of the semiconductor substrate SB including the upper surface of each of the source region SR, the contact region BC and the drain region DR and the upper surface of the gate electrode G1 are exposed. The dielectric film IF4 is a silicide block film for preventing a silicide layer from being formed in a place other than a desired place in a subsequent silicide step.

Subsequently, a silicide layer S1 is formed by a well-known salicide process. The silicide layer S1 is not formed in the upper surface of the semiconductor substrate SB between the gate electrode G1 and the drain region DR, the side surface of the gate electrode G1 on the drain region DR side and a part of the upper surface of the gate electrode G1, which are covered by the dielectric film IF4.

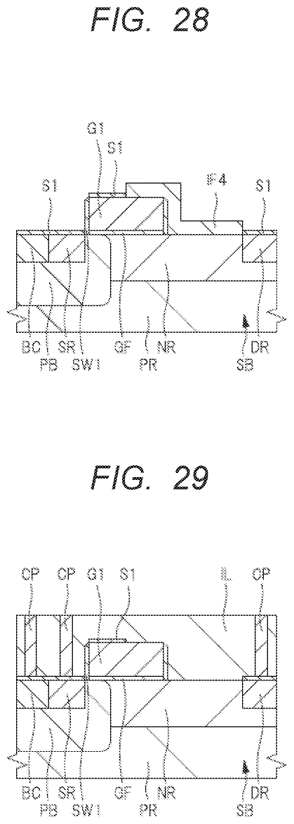

Next, as shown in FIG. 29, an interlayer dielectric film IL covering the upper surface of the semiconductor substrate SB, the gate electrode G1 and the silicide layers S1 is formed by, for example, a CVD method. In FIG. 29, illustration of the dielectric film IF4 is omitted assuming that the dielectric film IF4 is a part of the interlayer dielectric film IL. The interlayer dielectric film IL can be formed, for example, by laminating a relatively thin silicon nitride film, and a silicon oxide film formed on the silicon nitride film and having a larger film thickness than the silicon nitride film and the gate electrode G1. Subsequently, the upper surface of the interlayer dielectric film IL is planarized by, for example, CMP (Chemical Mechanical Polishing) method. After this planarization step, the gate electrode G1 remains covered with the interlayer dielectric film IL.

Subsequently, using a photolithography technique and a dry etching method, a plurality of contact holes, which are through holes penetrating the interlayer dielectric film IL, are formed in the interlayer dielectric film IL. Each of the plurality of contact holes exposes an upper surface of the silicide layer S1 on each of the source region SR and the contact region BC and an upper surface of the silicide layer S1 on the drain region DR. The contact hole formed in the region not shown in FIG. 29 exposes an upper surface of the silicide layer S1 on the gate electrode G1.

Subsequently, a contact plug CP is formed in each of the contact holes. The contact plug is mainly made of tungsten (W), for example. Here, for example, a metal film is formed on the semiconductor substrate SB including the inside of the contact hole by a sputtering method or the like, and the inside of the contact hole is thus embedded, and then the metal film on the interlayer dielectric film IL is removed by a CMP method or the like. Thus, a contact plug CP made of a metal film left in the contact hole is formed. As shown in FIG. 2, it is conceivable that the contact plug CP on each of the source region SR and the contact region BC is formed so as to straddle the boundary between the source region SR and the contact region BC in plan view.

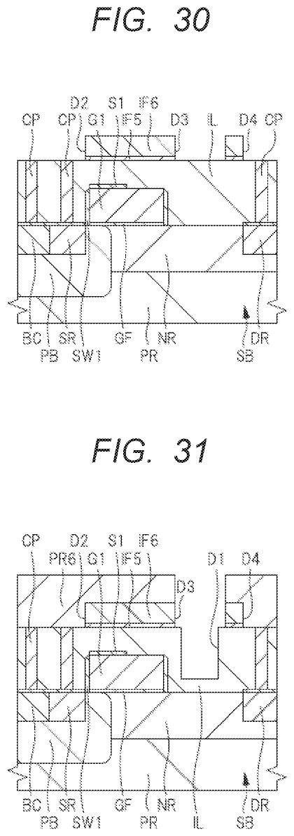

Next, as shown in FIG. 30, the dielectric films IF5, IF6 are sequentially laminated on the interlayer dielectric film IL. The dielectric film IF5 is formed of, for example, a silicon nitride film, and the dielectric film IF6 is formed of, for example, a silicon oxide film. The dielectric films IF5, IF6 can be formed by, for example, a CVD method.

Subsequently, wiring trenches D2, D3, and D4 are formed penetrating through the laminated film formed of the dielectric films IF5, IF6 by using a photolithography technique and a dry etching method. The wiring trench D2 exposes an upper surface of the contact plug CP on each of the source region SR and the contact region BC. The wiring trench D4 exposes the upper surface of the contact plug CP on the drain region DR. In a region (not shown), a wiring trench exposing the upper surface of the contact plug on the gate electrode G1 is also formed. On the other hand, the contact plug CP is not exposed on the bottom surface of the wiring trench D3. However, the wiring trench D3 is connected to the wiring trench D2 or the wiring trench on the gate electrode G1 in a region not shown in FIG. 30. A part of the wiring trench D3 is formed directly above the region between the gate electrode G1 and the drain region DR.

Next, as shown in FIG. 31, the trench D1 is formed on the upper surface of the interlayer dielectric film IL directly below the wiring trench D3 by performing a dry etching using the photoresist film PR6 as a mask. The photoresist film PR6 exposes the bottom surface of the wiring trench D3 and covers other region. The trench D1 has a predetermined depth from the upper surface of the interlayer dielectric film IL. The bottom surface of the trench D1 is located above the upper surface of the gate dielectric film GF. The trench D1 is formed on the semiconductor substrate SB between the region under the gate electrode G1 and the drain region DR. The trench D1 does not overlap the gate electrode G1 and the drain region DR.

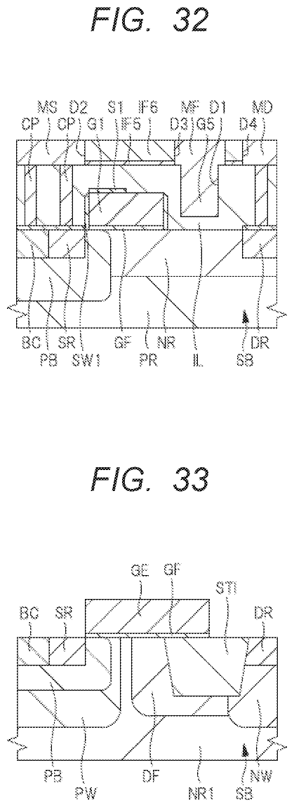

Next, as shown in FIG. 32, after the photoresist film PR6 is removed, a conductive film is formed to embed the inside of each of wiring trenches D2, D3 and D4, and the trench D1. Here, as the conductive film, a metal film mainly made of copper (Cu) is embedded in each of wiring trenches D2, D3 and D4 and the trench D1. As a result, a source wiring MS formed of the metal film is formed in the wiring trench D2. In addition, a drain wiring MD formed of the metal film is formed in the wiring trench D4. A wiring MF formed of the metal film is formed in the wiring trench D3. A field plate electrode G5 formed of the metal film is formed in the trench D1.

When forming the metal film, first, a thin copper film, which is a seed film, is formed on the interlayer dielectric film IL by, for example, a sputtering method. The seed film is also formed in the trench. Subsequently, a copper film, which is a main conductive film, is formed on the seed film by plating method. Thus, the metal film formed of the seed film and the main conductive film can be formed. Thereafter, the metal film on the dielectric film IF6 is removed using, for example, a CMP method to expose an upper surface of the dielectric film IF6, thereby leaving the metal film only in the respective trenches. As a result, the source wiring MS, wiring MF, the drain wiring MD, and the field plate electrode G5, which are formed of the metal film, are formed. At this time, in a region which is not shown, a gate wiring is also formed in the wiring trench directly above the gate electrode G1.

The wiring trench D3 and the wiring MF are located directly above the trench D1 and the field plate electrode FP. The wiring MF in the wiring trench D3 is integrally formed with the field plate electrode FP in the trench D1.

The source wiring MS is a source wiring that supplies a source potential to the source region SR, the contact region BC, and the body layer PB via the contact plug CP. The wiring MF is integrally formed with the source wiring MS (see FIG. 2). For this reason, the field plate electrode G5 is supplied with a source potential via the wirings MF and MS. The field plate electrode G5 is supplied with the gate potential via the wiring MF and the gate wiring when the field plate electrode G5 and the wiring MF are connected to the gate wiring instead of the source wiring MS. In this way, the source wiring MS, the wiring MF, the drain wiring MD and the field plate electrode G5 can be formed by a so-called damascene method. In particular, the wiring MF and the field plate electrode G5 can be formed by a so-called dual damascene process.

Through the above steps, the LDMOS including at least the body layer PB, the source region SR, the drain region DR, and the gate electrode G1 is formed. The LDMOS according to the present embodiment further includes a field plate electrode G5 and a contact region BC.

### Effects of Present Embodiment

In the present embodiment, the drain breakdown voltage of the end portion of the drain-side gate electrode can be improved by supplying a source potential or a gate potential to the field plate electrode G5 provided separately from the gate electrode G1 in the LDMOS.

Further, by supplying a source potential or a gate potential to the field plate electrode G5, the vicinity of the interface between the semiconductor substrate SB and the interlayer dielectric film IL directly below the field plate electrode G5 is depleted by potential modulation. As a result, the electronic current flows away from the interface in the semiconductor substrate SB, so that the hot carrier injection resistance can be improved. In the present embodiment, the field plate electrode G5 is made of a material having a large work function with respect to the semiconductor region NR located under the interlayer dielectric film IL directly below the field plate electrode G5. Thereby, the improvement effect for the hot carrier injection can be effectively obtained.

In the present embodiment, unlike the first embodiment, in the step of forming wirings, the field plate electrode G5 is formed in the trench D1 formed in the interlayer dielectric film IL. Therefore, a field plate effect can be obtained without forming the dielectric films IF1 to IF3 thicker than the gate dielectric film GF on the semiconductor substrate SB between the gate electrode G1 and the drain region DR. Further, there is no need to perform a step of forming the polysilicon film and a step of patterning or performing an etch back to the polysilicon film in order to form the field plate electrode.

As described above, in the present embodiment, it is possible to realize the LDMOS having a high breakdown voltage and a high hot carrier injection resistance. That is, the performance of the semiconductor device can be improved.

Although the invention made by the present inventor has been specifically described based on the embodiment, the present invention is not limited to the as described above embodiment, and it is needless to say that various modifications can be made without departing from the gist thereof

What is claimed is:

1. A semiconductor device comprising:
a semiconductor substrate having an upper surface and a lower surface;
an n-type first semiconductor region formed in the semiconductor substrate and having a predetermined depth from the upper surface of the semiconductor substrate;
a p-type second semiconductor region formed in the semiconductor substrate so as to be adjacent to the first semiconductor region in a first direction along the upper surface of the semiconductor substrate, the second semiconductor region having a predetermined depth from the upper surface of the semiconductor substrate;
an n-type source region formed in an upper surface of the second semiconductor region;
an n-type drain region formed in an upper surface of the first semiconductor region;
a gate electrode formed on the second semiconductor region between the source region and the drain region via a gate dielectric film; and
a first electrode formed on the first semiconductor region between the gate electrode and the drain region via a first dielectric film having a larger film thickness than the gate dielectric film,
wherein the gate electrode and the first electrode are next to each other, and
wherein the first electrode is formed of a material having a larger work function than the first semiconductor region located directly below the first electrode.

2. The semiconductor device according to claim 1,
wherein the first electrode comprises p-type silicon, copper or platinum.

3. The semiconductor device according to claim 1,
wherein a part of the gate electrode is located on the first dielectric film.

4. The semiconductor device according to claim 1,
wherein the first dielectric film covers the upper surface of the semiconductor substrate between the gate electrode and the drain region, a side surface of the gate electrode on the drain region side, and a part of an upper surface of the gate electrode.

5. The semiconductor device according to claim 4,
wherein the first electrode is in contact with the first dielectric film covering the side surface of the gate electrode on the drain region side.

6. The semiconductor device according to claim 5,
wherein the first electrode is formed in a sidewall spacer shape.

7. The semiconductor device according to claim 1,
wherein the first electrode is continuously formed in contact with an upper surface of the first dielectric film located between the gate electrode and the drain region in the first direction, a side surface of the first dielectric film covering the side surface of the gate electrode on the drain region side, and the upper surface of the first dielectric film on the upper surface of the gate electrode, and
wherein, between a laminated film formed of the first dielectric film and the first electrode and the drain region, a sidewall spacer formed of a second dielectric film covering a side surface of the laminated film on the drain region side and exposing the drain region.

8. The semiconductor device according to claim 1,
wherein the first dielectric film configures an interlayer dielectric film covering the gate electrode and the upper surface of the semiconductor substrate,
wherein the interlayer dielectric film has a trench directly above the semiconductor substrate between the gate electrode and the drain region, and
wherein the first electrode is formed in the trench.

9. A method of manufacturing a semiconductor device, comprising:
(a) preparing a semiconductor substrate having an upper surface and a lower surface;
(b) forming an n-type first semiconductor region having a predetermined depth from the upper surface of the semiconductor substrate in the semiconductor substrate;
(c) forming a gate electrode on the first semiconductor region via a gate dielectric film;
(d) forming a p-type second semiconductor region in the semiconductor substrate so as to be adjacent to the first semiconductor region, the second semiconductor region having a predetermined depth from the upper surface of the semiconductor substrate;
(e) forming an n-type source region having a predetermined depth from an upper surface of the second semiconductor region, and forming an n-type drain region having a predetermined depth from an upper surface of the first semiconductor region;
(f) forming a laminated film formed of a first dielectric film having a larger film thickness than the gate dielectric film and a first electrode on the first dielectric film, so as to continuously cover the upper surface of the semiconductor substrate between the gate electrode and the drain region and a side surface of the gate electrode on the drain region side;
(g) forming a second dielectric film covering the upper surface of the semiconductor substrate, the gate electrode and the laminated film; and
(h) forming a sidewall spacer formed of the second dielectric film by etching back the second dielectric film, the sidewall spacer exposing an upper surface of each of the semiconductor substrate, the gate electrode and the laminated film and covering a side surface of the laminated film on the drain region side,
wherein the first electrode is formed of a material having a larger work function than the first semiconductor region located directly below the first electrode.

10. The method according to claim 9,
wherein the first electrode comprises p-type silicon, copper or platinum.

11. A method of manufacturing a semiconductor device, comprising:
(a) preparing a semiconductor substrate having an upper surface and a lower surface;
(b) forming an n-type first semiconductor region having a predetermined depth from the upper surface of the semiconductor substrate in the semiconductor substrate;
(c) forming a gate electrode directly above the first semiconductor region via a gate dielectric film;
(d) forming a p-type second semiconductor region in the semiconductor substrate so as to be adjacent to the first semiconductor region, the second semiconductor region having a predetermined depth from the upper surface of the semiconductor substrate directly below the gate electrode;
(e) forming an n-type source region in the second semiconductor region including an upper surface of the second semiconductor region, and forming an n-type drain region in the first semiconductor region including an upper surface of the first semiconductor region;
(f) forming an interlayer dielectric film on the semiconductor substrate so as to cover the gate electrode;
(g) forming a trench reaching a predetermined depth of the interlayer dielectric film from an upper surface of the interlayer dielectric film, directly above the semiconductor substrate between the gate electrode and the drain region; and
(h) forming a first electrode in the trench,
wherein a shortest distance between the upper surface of the semiconductor substrate and the first electrode is larger than a film thickness of the gate dielectric film, and
wherein the first electrode is formed of a material having a larger work function than the first semiconductor region located directly below the first electrode.

12. The method according to claim 11,
wherein the first electrode comprises p-type silicon, copper or platinum.
